(19) United States
(12) Patent Application Publication
(10) Pub. No.: US 2002/0066585 A1
(43) Pub. Date: Jun. 6, 2002

(54) ENCAPSULATING SENSOR AND METHOD OF MAKING SAME

(76) Inventors: JEFFREY REID, LONGFORD MILLS (CA); PAUL RAVENSDALE, MISSISSAUGA, ONTARIO (CA)

Correspondence Address: MICHAEL F. SCALISE, HODGSON, RUSS, ANDREWS, WOODS & GOODYEAR, LLP, ONE M & T PLAZA, SUITE 2000, BUFFALO, NY, 14203, US

(21) Appl. No.: 09/159,365

(22) Filed: Sep. 23, 1998

Related U.S. Application Data
(60) Provisional application No. 60/059,608, filed on Sep. 23, 1997.

(51) Int. Cl. H01L 23/28; H05K 5/06

(52) U.S. Cl. 174/52.2

(57) ABSTRACT

An anti-theft and/or inventory control device which can be permanently or temporarily installed as an insert within a textile product, such as apparel, footwear, bags accessories, tents, soft goods and others. The device has a sensor which is encapsulated in a waterproof carrier, such as a woven fabric. The fabric with the encapsulated sensor becomes an insert which can be sewn into a garment or product, preferably into a seam or hem. Such installation of the insert into a product can be permanent or temporary.

### CROSS-REFERENCE TO A RELATED APPLICATION

Applicants hereby claim priority on earlier filed provisional patent application Serial No. 60/059,608, filed Sep. 23, 1997, which is incorporated herein by reference.

### BACKGROUND OF THE INVENTION

1. Field of the Invention

The present invention relates generally to a product which will allow rapid deployment of permanent securing and inventory control devices into various soft goods such as garments for the retail industry.

2. Prior Art

Current solutions to this problem is to use detachable sensors which are either large snap-on sensors attached to the outside of the garment or removable fashion or content labels which are usually sewn into the garment.

Although these solutions offer some protection to the retail industry, their effectiveness is limited to the following:

large sensors can be compromised past the security system by enclosing the sensor tightly with the thief's palm

removable labels sewn in the garment can be pulled out of the garment before leaving the store.

U.S. Pat. No. 4,626,311 discloses an anti-theft device attached to a cloth product. The method of attaching the anti-theft device is by fusion. This is not applicable for most apparel products.

U.S. Pat. No. 4,151,405 discloses an anti-theft system having a magnetic sensing field for detecting a security device as it passes through an interrogation zone of the anti-theft system to produce a detectable signal.

U.S. Pat. No. 5,583,489 discloses an anti-theft device label which allows the device to be removed after the sales transaction. It also allows the anti-theft device to be detected and removed by a would-be thief prior to departing the store and therefore rendering the security system ineffective.

### SUMMARY OF THE INVENTION

The purpose of the invention is to provide a strong waterproof product which can be permanently installed into various soft goods while in manufacturing in a concealed location as to avoid detection and cannot be is removed without substantial damage to the product it is deployed within.

This invention enables security sensors and radio frequency identification sensors to be inserted into garments and other soft good products permanently. Whereby the security sensor or radio frequency identification sensor enclosed in a waterproof encapsulation is installed into the garment totally enclosed into the fabric of the garment of soft good products.

The purpose of producing a product in this manner is to make the detection device unnoticeable to the would-be thief. Current methods of protecting soft goods are labor intensive and noticeable to the potential thief and can be removed potentially with little or no damage to the product.

This insert is best deployed in the manufacturing stage of soft goods to ensure the most undetectable position for the sensor. This product will be used in conjunction with the suppliers of retailers which use deactivated equipment at the point of sale.

### BRIEF DESCRIPTION OF THE DRAWINGS

For a further understanding of the invention, as well as its characterizing features, reference should now be made to the accompanying drawings wherein:

FIG. 1 is a side view of the embodiment of the encapsulated security product in a continuous tape form.

FIG. 2 is an overhead view of the embodiment of the encapsulated security product in a continuous tape form.

FIG. 3 is a bisected view of the encapsulated security product showing a waterproof pocket.

FIG. 4 is an overhead view of the encapsulated security product showing a sewable edge.

FIG. 5 is an overhead view of the encapsulated security product in use with a T-shirt.

FIG. 6 is an overhead view of the encapsulated product in use with a coat.

### DETAILED DESCRIPTION OF THE PREFERRED EMBODIMENT

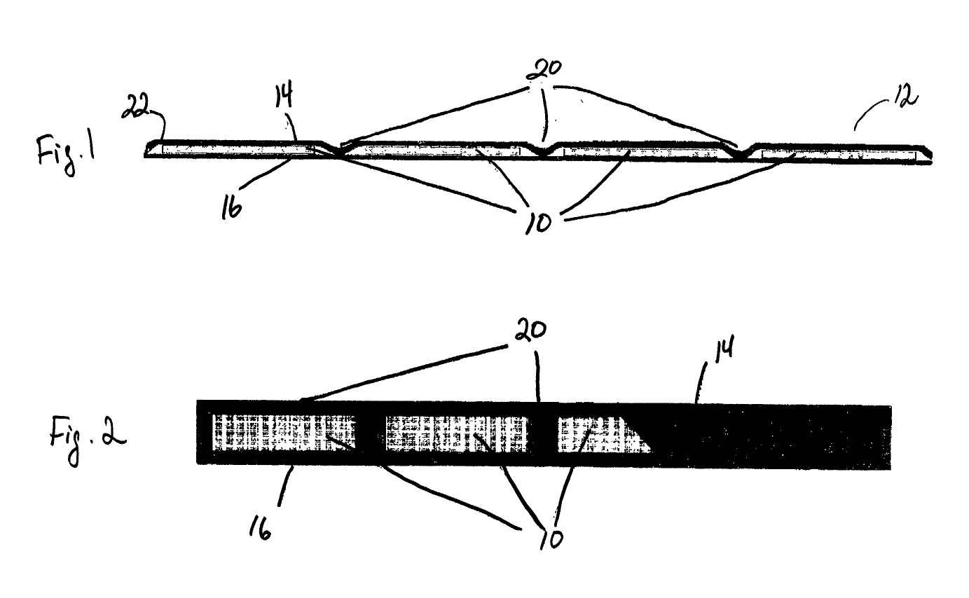

FIG. 1 shows a bisected side view where coated nylon tape 14 is ultrasonically welded with nylon tape 16 in a rectangular seal as to produce waterproof pocket around sensors 10, thus producing a sewable edge all around sensors 10. Each security sensor 10 is an insert that is encapsulated in a fabric 12 which is coated with a polyurethane layer and then ultrasonically welded on all four sides 20 to make a waterproof pouch with four sewable edges, as illustrated in FIG. 1. Security sensor 10 which is encapsulated is either acoustomagnetic, magnetic, RF or RFID capable of interrupting a magnetic sensing field. The inserted sensor 10 is intended to be permanently fixed in the garment or soft good. As shown in fabric 12 can be a tape having one or more sensors 10 inserted into it.

Fabric 12 which encapsulates sensor 10 can be any woven, coated, synthetic fabric which can be sewn, heat sealed or ultrasonically sealed to the garment or soft good product fabric. The preferred material of fabric 12 is nylon.

FIG. 2 shows an overhead view half where coated nylon strip 14 is pulled back exposing encapsulated sensors 10 installed on nylon strip 16. This overhead also shows the marked areas of the ultrasonic weld 20 with its rectangular signature to encapsulate the sensors 10.

To remove sensor 10 from the product, the seam, hem or other location that the sensor has been affixed to would have to be opened carefully with a high probability of damaging the garment in some significant way. In addition, security sensor 10 of the present invention is protected from effects of the manufacturing as well as subsequent washing or normal use of the garment or soft good. Sensor 10 can be activated and/or deactivated when the it is encapsulated into fabric 12.

In order to manufacture the encapsulated sensor 10 of the present invention, coated nylon fabric 12 cut in the appropriate width is established on a feeder and sent through an applicator where sensors 10 are transferred onto a nylon strip 16, similar to that shown in FIGS. 1-4.

The nylon strip 16 with the sensor applied is then aligned with another similar strip of nylon 14 effectively sandwiching sensors 10 between the nylon strips 14 and 16, coated side of the nylon is against sensors 10 on both sides. The two strips of nylon are then forwarded to an ultrasonic welding device which welds the fabric on all four sides enclosing each sensor 10 in a waterproof nylon carrier. FIG. 3 shows a waterproof insert 22 created by ultrasonic welding of nylon strip 14 and nylon strip 26.

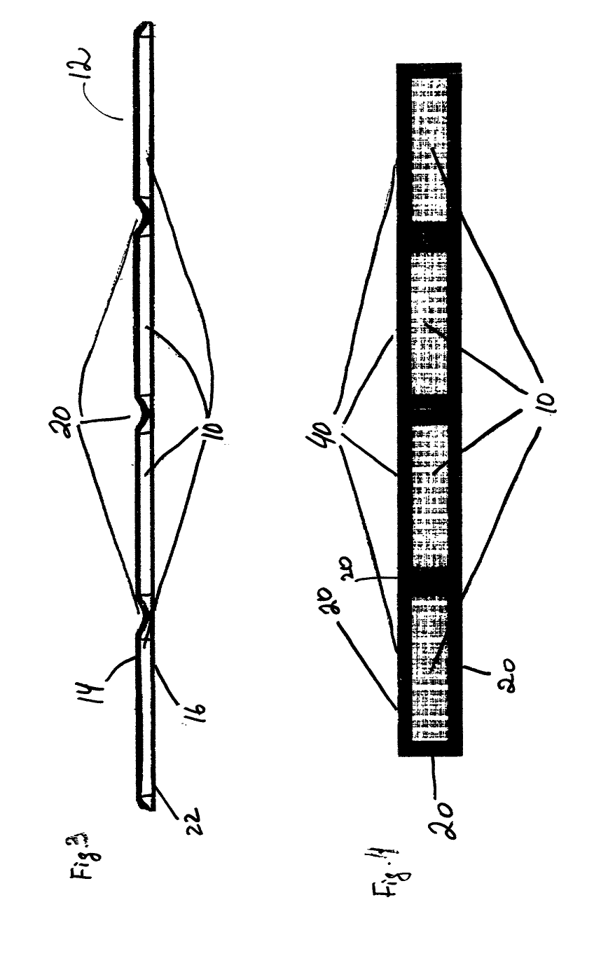

The welded nylon strips 14 and 16 are then die cut to produce an individual insert 22 which has four sides to be used in the attaching process to the fabric of the garment. FIG. 4 shows a sewable edge 40 all around the sensors 10 produced by ultrasound weld 20.

The encapsulated sensors 10 can also bypass the die cut and be fed onto a roller and delivered as a chain if required.

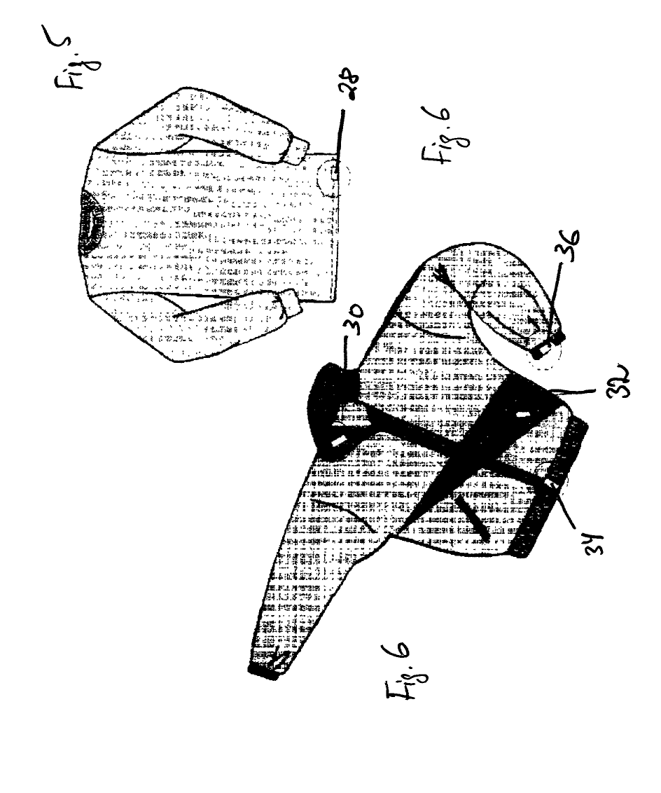

One method of using encapsulated sensor 10 is to take insert 22 using conventional sewing equipment and attach one edge to insert 22 onto the bottom edge of an open hem turning insert 22 inside of the fabric, as illustrated in FIG. 5 at 28. Such process will totally enclose insert 22 into the fabric of a garment.

The second method of using encapsulated sensor 10 is similar to the method described above except that attaching insert 22 to the fabric of a garment can be done through heat sealing or ultrasonic weld sealing to the bottom of an open hem when using synthetic fabrics.

The third method of deployment is to take insert 22 and attach it using sewing equipment into a seam of sufficient dimension to totally enclose insert 22 in the fabric of the garment or other soft good.

The fourth method is the same as the third method except that the heat sealing equipment or ultrasonic welding equipment is used to totally enclose insert 22 into the seam of the garment or other products.

The fifth method of incorporating insert 22 into a garment is to attach the insert into an area of the garment, other than a seam or hem, where there are two layers of fabric. The insert can be attached to such an area by at least one of its edges, i.e. inside a collar, as shown in FIG. 6 at 30, inside a pocket (FIG. 5 at 32), inside a waistband (FIG. 6 at 34) or inside a cuff (FIG. 6 at 36).

The encapsulated sensors come with a coded manual as to what method and location the sensor should be deployed to set an industry standard for various products.

What is claimed is:

1. A device for anti-theft or inventory control which can be permanently or removably installed in a product, the device comprising a sensor encapsulated between a first and a second layers of waterproof fabric, which layers are sealed together at their edges to ensure that the sensor remains encapsulated between the first and the second layers.

2. The device of claim 1, wherein the waterproof fabric is coated nylon.

3. The device of claim 1, wherein the sensor is either acoustomagnetic, magnetic, RF or RFID.

4. The device of claim 1, wherein he first and the second layers are sealed together by ultrasonic welding or heat sealing.

5. A method of manufacturing a device for anti-theft or inventory control, the method comprising applying a sensor to a first layer of waterproof fabric, covering the first layer of waterproof fabric and the sensor by a second lawyer of waterproof fabric, so that the sensor is sandwiched between the first and the second layers, and sealing the layers together at the edges to ensure that the sensor remains encapsulated between the layers.

6. The method of claim 5, wherein sealing the first and the second layers is accomplished by ultrasonic welding or hear sealing.

7. A method of manufacturing a product with an insert for anti-theft or inventory control, the method comprising the steps of:
applying a sensor to a first layer of waterproof fabric,
covering the first layer of waterproof fabric and the sensor by a second lawyer of waterproof fabric,
providing the insert by sealing the layers together at the edges to ensure that the sensor remains encapsulated between the layers, and
incorporating the insert into the product.

8. The method of claim 7, wherein incorporating the insert into the product includes attaching the insert to the product by sewing equipment.

9. The method of claim 7, wherein incorporating the insert into the product is accomplished by ultrasonic welding or heat sealing.
